(19) United States
(12) Patent Application Publication
(10) Pub. No.: US 2025/0031411 A1
(43) Pub. Date: Jan. 23, 2025

(54) VERTICAL TRANSISTOR, STORAGE UNIT AND MANUFACTURING METHOD THEREFOR

(71) Applicant: BEIJING SUPERSTRING ACADEMY OF MEMORY TECHNOLOGY, Daxing District, Beijing (CN)

(72) Inventors: Huihui LI, Beijing (CN); Yunsen ZHANG, Beijing (CN); Guilei WANG, Beijing (CN); Chao ZHAO, Beijing (CN)

(73) Assignee: BEIJING SUPERSTRING ACADEMY OF MEMORY TECHNOLOGY, Daxing District, Beijing (CN)

(21) Appl. No.: 18/714,965

(22) PCT Filed: Dec. 7, 2022
(86) PCT No.: PCT/CN2022/137310

§ 371 Date: May 30, 2024

(30) Foreign Application Priority Data
Aug. 18, 2022 (CN) 202210993592.6

(51) Int. Cl. H01L 29/786; H01L 29/06; H01L 29/423; H01L 29/66; H10B 12/00; H10B 61/00

(52) U.S. Cl. CPC H01L 29/78642; H01L 29/42376; H01L 29/66742; H01L 29/78645; H10B 12/056; H10B 12/36; H10B 12/482; H10B 61/22; H01L 29/0603; H01L 29/42364

(57) ABSTRACT

A vertical transistor, and a memory cell and a manufacturing method therefor are provided. The vertical transistor includes: a source electrode disposed on a substrate; a drain electrode which is disposed at a side, away from the substrate, of the source electrode; and a gate electrode and a semiconductor layer, which are in the same layer, and are disposed between the source electrode and the drain electrode in a first direction which is perpendicular to the substrate. The gate electrode at least comprises a column-shaped first gate electrode extending in the first direction. The semiconductor layer comprises a first semiconductor layer and a second semiconductor layer which are in the same layer and spaced apart from each other, and the first gate electrode is disposed between the first semiconductor layer and the second semiconductor layer.

### CROSS-REFERENCE TO RELATED APPLICATIONS

This application is a U.S. national stage of International Application No. PCT/CN2022/137310, filed on Dec. 7, 2022, which claims priority to Chinese Patent Application No. 202210993592.6, filed on Aug. 18, 2022, the contents of which are incorporated herein by reference in their entireties.

### TECHNICAL FIELD

The present application relates to the technical field of semiconductors, and in particular, relates to a vertical transistor, and a memory cell and a manufacturing method therefor.

### BACKGROUND

With the development of semiconductor device integration technology, for semiconductor devices represented by a memory, the size of a memory cell structure in the memory is getting smaller and smaller to increase the storage density of the memory.

### SUMMARY

The present application provides a vertical transistor, and a memory cell and a manufacturing method therefor.

Some embodiments of the present application provide a vertical transistor. The vertical transistor includes:
a source electrode disposed on a substrate;
a drain electrode disposed above the source electrode and stacked with the source electrode; and
a gate electrode and a semiconductor layer, which are in the same layer, and are disposed between the source electrode and the drain electrode in a first direction which is perpendicular to the substrate, wherein
the gate electrode includes at least a column-shaped first gate electrode extending in the first direction; and the semiconductor layer includes a first semiconductor layer and a second semiconductor layer which are in the same layer and spaced apart from each other, and the first gate electrode is disposed between the first semiconductor layer and the second semiconductor layer.

Some embodiments of the present application provide a memory cell. The memory cell includes: a word line, a bit line, and a vertical transistor, wherein
the bit line is disposed at a side, away from a drain electrode, of a source electrode of the vertical transistor and is connected to the source electrode; the word line is connected to a gate electrode of the vertical transistor; the drain electrode and the source electrode are stacked together, the vertical transistor includes a semiconductor layer which are in the same layer as the gate electrode, and the gate electrode and the semiconductor layer are both disposed between the source electrode and the drain electrode in a first direction which is perpendicular to a substrate; the gate electrode includes at least a column-shaped first gate electrode extending in the first direction; the semiconductor layer includes a first semiconductor layer and a second semiconductor layer which are in the same layer and spaced apart from each other, and the first gate electrode is disposed between the first semiconductor layer and the second semiconductor layer; and
the bit line includes a first portion and a second portion connected to each other, an orthographic projection of the first portion and an orthographic projection of the first semiconductor layer of the vertical transistor on the substrate have an overlapping area, and the orthographic projection of the first portion and an orthographic projection of the second semiconductor layer of the vertical transistor on the substrate are separated from each other; and an orthographic projection of the second portion and the orthographic projection of the first semiconductor layer on the substrate are separated from each other, and the orthographic projection of the second portion and the orthographic projection of the second semiconductor layer on the substrate have an overlapping area.

Some embodiments of the present application provide a method for manufacturing a memory cell. The method includes:
forming a first silicon-doped conductive layer, a sacrificial semiconductor layer, and a second silicon-doped conductive layer sequentially at a side of a substrate;
forming a plurality of first trenches through a patterning process to distinguish a plurality of transistor row regions, where each of the first trenches is flanked by a source row formed by the first silicon-doped conductive layer, a first sacrificial structure row formed by the sacrificial semiconductor layer, and a drain row formed by the second silicon-doped conductive layer which are stacked together;
etching back, for each of the transistor row regions, the first sacrificial structure row exposed at a side surface of the first trench to form a sacrificial structure row, where sidewalls of the source row, the sacrificial structure row, and the drain row form a U-shaped trench;
forming, for each of the transistor row regions, a semiconductor material layer in the U-shaped trench;
forming a plurality of second trenches perpendicular to the first trenches on the substrate through the patterning process to distinguish a plurality of transistor regions, where each of the transistor regions includes a source electrode formed by the source row, a semiconductor layer formed by the semiconductor material layer, and a drain electrode formed by the drain row stacked together; and a sacrificial structure formed by the sacrificial structure row is in the same layer as the semiconductor layer and is disposed between a first semiconductor layer and a second semiconductor layer included in the semiconductor layer;
removing the sacrificial structure to form a hole; and
adding a conductive material in the hole and on a sidewall of the semiconductor layer through a coating process, and patterning the conductive material to form a gate electrode including a first gate electrode and form a word line connected to the first gate electrode.

### BRIEF DESCRIPTION OF THE DRAWINGS

The above and/or additional aspects and advantages of the present application will become apparent and readily understood from the following description of embodiments in conjunction with the accompanying drawings, in which:

FIG. 1 is a schematic structural diagram of a vertical transistor according to some embodiments of the present application;

FIG. 2 is a schematic cross-sectional structural diagram of the vertical transistor shown in FIG. 1 along the AA direction;

FIG. 3 is a schematic structural diagram of another vertical transistor according to some embodiments of the present application;

FIG. 4 is a schematic structural diagram of a memory cell according to some embodiments of the present application;

FIG. 5 is a schematic structural diagram of another memory cell according to some embodiments of the present application;

FIG. 6 is a flowchart illustrating a method for manufacturing a memory according to some embodiments of the present application;

FIG. 7 is a schematic structural diagram illustrating a first photoresist structure and a first mask structure prepared in a method for manufacturing a memory according to some embodiments of the present application;

FIG. 8 is a schematic structural diagram illustrating an initial stacked structure row prepared in a method for manufacturing a memory according to some embodiments of the present application;

FIG. 9 is a schematic structural diagram illustrating a protection layer prepared in a method for manufacturing a memory according to some embodiments of the present application;

FIG. 10 is a schematic structural diagram illustrating an arc-shaped slot prepared in a method for manufacturing a memory according to some embodiments of the present application;

FIG. 11 is a schematic structural diagram illustrating a metal layer prepared in a method for manufacturing a memory according to some embodiments of the present application;

FIG. 12 is a schematic structural diagram illustrating an initial bit line layer prepared in a method for manufacturing a memory according to some embodiments of the present application;

FIG. 13 is a schematic structural diagram illustrating a first planarization layer prepared in a method for manufacturing a memory according to some embodiments of the present application;

FIG. 14 is a schematic structural diagram illustrating a first planarization structure prepared in a method for manufacturing a memory according to some embodiments of the present application;

FIG. 15 is a schematic structural diagram illustrating a stacked structure row prepared in a method for manufacturing a memory according to some embodiments of the present application;

FIG. 16 is a schematic structural diagram illustrating a semiconductor material layer prepared in a method for manufacturing a memory according to some embodiments of the present application;

FIG. 17 is a schematic structural diagram illustrating a second planarization layer prepared in a method for manufacturing a memory according to some embodiments of the present application;

FIG. 18 is a schematic cross-sectional structural diagram along the BB direction illustrating a mask structure prepared from the structure shown in FIG. 14 in a method for manufacturing a memory according to some embodiments of the present application;

FIG. 19 is a schematic structural diagram illustrating a bit line prepared in a method for manufacturing a memory according to some embodiments of the present application;

FIG. 20 is a schematic structural diagram illustrating an initial word line layer prepared in a method for manufacturing a memory according to some embodiments of the present application;

FIG. 21 is a schematic structural diagram illustrating a first sub-gate electrode and a second sub-gate electrode prepared in a method for manufacturing a memory according to some embodiments of the present application; and

FIG. 22 is a schematic structural diagram illustrating a third dielectric layer prepared in a method for manufacturing a memory according to some embodiments of the present application.

### DESCRIPTION OF THE REFERENCE NUMERALS

100—substrate;
10—transistor;
11—source electrode; 12—semiconductor layer; 121—first semiconductor layer; 122—second semiconductor layer; 13—gate electrode; 131—first sub-gate electrode; 132—second sub-gate electrode; 14—drain electrode; 15—gate insulating layer; 151—first gate insulating layer; 152—second gate insulating layer;
20—bit line; 21—first portion; 22—second portion; 23—third portion;
30—connection structure; 31—silicide structure; 32—metal structure;
40—dielectric structure;
101—first silicon-doped conductive layer; 102—sacrificial semiconductor layer; 103—second silicon-doped conductive layer; 104—first photoresist structure; 105—first mask structure;
106—initial stacked structure row; 1011—source row; 1021—first sacrificial structure row; 1031—drain row;
107—protection layer; 1071—protection structure;
108—arc-shaped slot; 109—metal layer; 110—initial bit line layer; 111—first planarization layer; 1111—first planarization structure; 1112—third planarization structure;
112—stacked structure row; 1121—sacrificial semiconductor material layer; 113—semiconductor material layer;
114—second planarization layer; 1141—second planarization structure;
115—mask structure; 1151—first sub-mask structure; 1152—second sub-mask structure;
116—stacked structure; 117—initial word line layer; 118—third dielectric layer; 119—first trench; and
120—second trench.

### DETAILED DESCRIPTION

Embodiments of the present application are described below in conjunction with the accompanying drawings in the present application. It should be understood that the embodiments set forth below in conjunction with the accompanying drawings are exemplary descriptions for explaining the present application, and do not limit the technical solutions of the inventive concept in the present application.

As will be understood by those skilled in the art, the singular forms “a”, “an”, “one”, and “the”, as used herein, are intended to include plural forms as well, unless specifically stated otherwise. It should be further understood that the term “include”, as used herein, refers to the presence of stated features, integers, steps, operations, elements, and/or components, but does not exclude the implementation of other features, information, data, steps, operations, elements, components, and/or combinations thereof, as supported in the art.

For clearer descriptions of the objects, technical solutions, and advantages of the present application, embodiments of the present application are further described in detail below with reference to the accompanying drawings.

The embodiments of the present application relate to a vertical structure transistor, and in particular, relates to a vertical gate-all-around (VGAA) transistor.

As the integration degree of the dynamic random access memory (DRAM) and the magnetoresistive random access memory (MRAM) is becoming increasingly higher, the size of transistors used in the memories is desired to reduce. Compared with a conventional planar transistor, the vertical transistor has a smaller projection area on a substrate, such that the vertical transistor has an extensive application space in future high-density DRAM, MRAM, and other memories.

However, the vertical structure transistor faces a bottleneck of further improvement of the driver current. For example, with a decrease of the size of the vertical structure transistor, an on-state current of the vertical structure transistor decreases, such that the driving performance of the transistor is reduced and the turn-on speed is slowed, which further affects the performance of the memory.

In addition, in the manufacturing process of the conventional memory, the semiconductor structure and the gate electrode of the vertical transistor are manufactured with a low accuracy, leading to a difference in the performance of the vertical transistors in the memory, which affects the performance of the memory.

The present application provides a vertical transistor, and a memory cell and a manufacturing method therefor, which aim to solve the above technical problems in the prior art.

The technical solutions of the present application will be described in detail below with reference to specific embodiments.

The embodiments of the present application provide a vertical transistor that is applicable to a memory or logic device.

The vertical transistor according to the embodiments of the present application will be described in detail below. For a better understanding of the solution, the vertical transistor of the present application will be described in conjunction with a bit line.

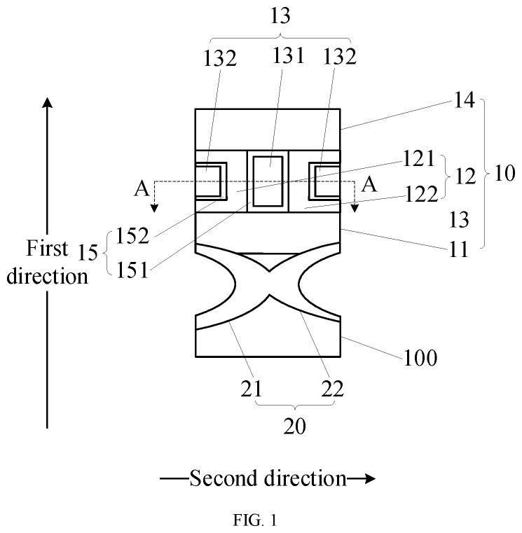

In the embodiments of the present application, as shown in FIG. 1, the vertical transistor includes: a source electrode 11, a drain electrode 14, a gate electrode 13, and a semiconductor layer 12.

In the embodiments of the present application, the source electrode 11 is disposed on a substrate 100, and the drain electrode 14 is disposed above the source electrode 11 and stacked with the source electrode 11. The gate electrode 13 and the semiconductor layer 12 are in the same layer, and the gate electrode 13 and the semiconductor layer 12 are both disposed between the source electrode 11 and the drain electrode 14 in a first direction which is perpendicular to the substrate 100. The gate electrode 13 includes at least a column-shaped first gate electrode 131 extending in the first direction, the semiconductor layer 12 includes a first semiconductor layer 121 and a second semiconductor layer 122 in the same layer and spaced apart from each other, and the first gate electrode 131 is disposed between the first semiconductor layer 121 and the second semiconductor layer 122.

In the vertical transistor 10 according to the embodiments of the present application, the semiconductor layer 12 includes the first semiconductor layer 121 and the second semiconductor layer 122 spaced apart from each other. The first gate electrode 131 is disposed between the first semiconductor layer 121 and the second semiconductor layer 122, such that the first gate electrode 131 can apply electric fields to the first semiconductor layer 121 and the second semiconductor layer 122 simultaneously so as to drive the first semiconductor layer 121 and the second semiconductor layer 122 simultaneously, enabling an improvement of an on-state current of the vertical transistor 10 and a further improvement of the performance of the vertical transistor 10.

In the embodiments of the present application, as shown in FIG. 1, the first semiconductor layer 121, the first gate electrode 131, and the second semiconductor layer 122 isolated from each other are arranged at a side of the source electrode 11 away from the substrate 100. In some embodiments, the first semiconductor layer 121 is arranged at a side of the first gate electrode 131 in a second direction, and the second semiconductor layer 122 is arranged at another side of the first gate electrode 131 in the second direction, i.e., the first semiconductor layer 121 and the second semiconductor layer 122 are distributed at two sides of the first gate electrode 131, such that the first gate electrode 131 can apply electric fields to the first semiconductor layer 121 and the second semiconductor layer 122 simultaneously so as to drive the first semiconductor layer 121 and the second semiconductor layer 122 simultaneously, enabling an improvement of an on-state current of the vertical transistor 10, resulting in an improvement of the driving capability and the turn-on speed of the vertical transistor 10, and a further improvement of the performance of the vertical transistor 10.

In the embodiments of the present application, the first semiconductor layer 121 extends from the source electrode 11 to the drain electrode 14 and is connected to the source electrode 11 and the drain electrode 14, respectively. The second semiconductor layer 122 extends from the source electrode 11 to the drain electrode 14 and is connected to the source electrode 11 and the drain electrode 14, respectively. Both the first semiconductor layer 121 and the second semiconductor layer 122 are insulated from the first gate electrode 131.

Optionally, in the embodiments of the present application, the first direction is a direction in which the source electrode 11 points to the drain electrode 14, and the second direction is a direction in which the first semiconductor layer 121 points to the second semiconductor layer 122.

In the embodiments of the present application, the first semiconductor layer 121 and the second semiconductor layer 122 spaced apart from each other are not directly connected physically, and can be isolated by full coating and etching processes during the manufacturing process, which will be described in detail in the subsequent manufacturing process, and is not detailed here.

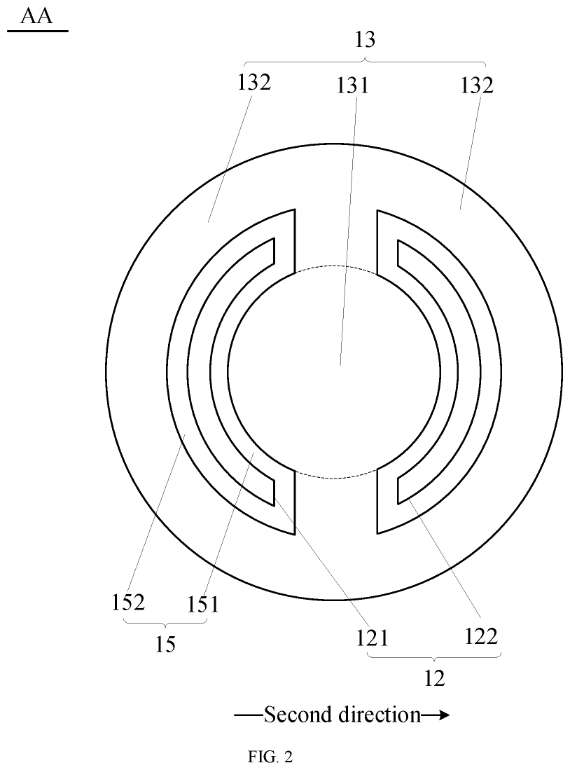

Optionally, as shown in FIG. 2, in an embodiment of the present application the gate electrode 13 further includes a second gate electrode 132 connected to the first gate electrode 131; and the second gate electrode 132 is arranged around outer side surfaces of the first semiconductor layer 121 and the second semiconductor layer 122.

In the embodiments of the present application, as shown in FIG. 2, the first gate electrode 131 has a circular cross-section, and a cross-section of the second gate electrode 132 has a circular outer boundary, such that the integral structure formed by the gate electrode 13, the semiconductor layer 12, and a gate insulating layer 15 has a circular cross-section.

In the embodiments of the present application, as shown in FIG. 2, the second gate electrode 132 is arranged around the outer side surfaces of the first semiconductor layer 121 and the second semiconductor layer 122, and the second gate electrode 132 is insulated from the first semiconductor layer 121 and the second semiconductor layer 122.

In the embodiments of the present application, as shown in FIG. 2, the second gate electrode 132 is connected to the first gate electrode 131, such that in the case that one of the first gate electrode 131 and the second gate electrode 132 is applied with a turn-on level, the other is also applied with the same turn-on level, such that both the first gate electrode 131 and the second gate electrode 132 can apply electric fields to the first semiconductor layer 121 and the second semiconductor layer 122 simultaneously, enabling a further improvement of an on-state current of the vertical transistor 10, resulting in an improvement of the driving capability and the turn-on speed of the vertical transistor 10, and a further improvement of the performance of the vertical transistor 10.

Optionally, as shown in FIG. 2, boundaries between the first gate electrode 131 and the second gate electrode 132 are indicated by the dotted line. However, in a real product, the first gate electrode 131 and the second gate electrode 132 are manufactured together, without the dotted line therebetween shown in FIG. 2.

Optionally, as shown in FIG. 1 and FIG. 2, the gate electrode 13 and the semiconductor layer 12 are insulated from each other by the gate insulating layer 15. In some embodiments, the gate insulating layer 15 includes a first gate insulating layer 151 and a second gate insulating layer 152. The first gate insulating layer 151 is arranged between the first semiconductor layer 121 and the first gate electrode 131, and between the second semiconductor layer 122 and the first gate electrode 131; and the second gate insulating layer 152 is arranged between the first semiconductor layer 121 and the second gate electrode 132, and between the second semiconductor layer 122 and the second gate electrode 132.

Optionally, as shown in FIG. 1 and FIG. 2, in the vertical transistor 10, the gate electrode 13 is the integral structure formed by the first gate electrode 131 and the second gate electrode 132. The gate electrode 13 is generally column-shaped, and two independent openings are disposed at different regions of an upper surface of the gate electrode 13, each extending to a lower surface. The two openings are respectively filled with the first semiconductor layer 121 and the second semiconductor layer 122, and the first semiconductor layer 121 and the second semiconductor layer 122 are insulated from the gate electrode 13 in the openings by the gate insulating layer 15.

Optionally, as shown in FIG. 1 and FIG. 2, the gate insulating layer 15 is filled in both of the openings, and the gate insulating layer 15 includes a first gate insulating layer 151 and a second gate insulating layer 152. The first gate insulating layer 151 is disposed at a sidewall of the opening close to the first gate electrode 131, and the second gate insulating layer 152 is disposed at a sidewall of the opening close to the second gate electrode 132. The first semiconductor layer 121 and the second semiconductor layer 122 are disposed in the corresponding openings and insulated from the gate electrode 13 by the first gate insulating layer 151 and the second gate insulating layer 152.

Optionally, the first gate insulating layer 151 and the second gate insulating layer 152 are both made of a dielectric material with a high k-value, such that while the insulating property is ensured, the thicknesses of the first gate insulating layer 151 and the second gate insulating layer 152 are reduced, which is beneficial to further reducing the volume of the vertical transistor 10.

Optionally, in an embodiment of the present application, the gate electrode 13 further includes a second gate electrode 132 arranged at an outer side surface of the first semiconductor layer 131 and/or an outer side surface of the second semiconductor layer 132.

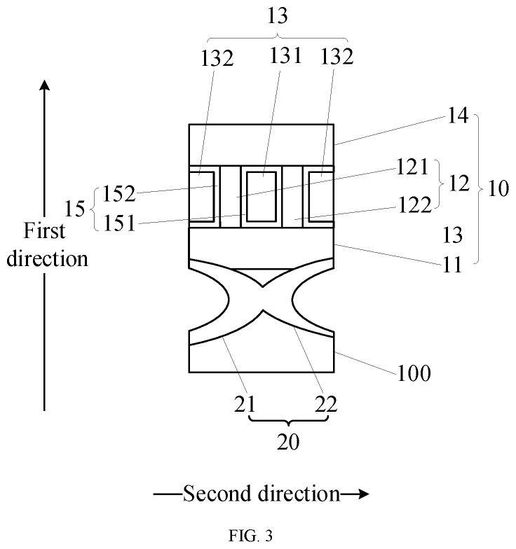

In the embodiments of the present application, as shown in FIG. 3, the second gate electrode 132 is also column-shaped and extending in the first direction, and the second gate electrode 132 is not connected to the first gate electrode 131, such that different levels can be independently input to the first gate electrode 131 and the second gate electrode 132, enabling an improvement of the control accuracy of an on-state current of the vertical transistor 10.

Optionally, as shown in FIG. 1 and FIG. 3, in an embodiment of the present application, an orthographic projection of the first gate electrode 131 and an orthographic projection of the second gate electrode 132 on the substrate 100 are both within an orthographic projection of the source electrode 11 or the drain electrode 14 on the substrate 100.

In the embodiments of the present application, as shown in FIG. 1 and FIG. 3, the orthographic projection of the first gate electrode 131 and the orthographic projection of the second gate electrode 132 on the substrate 100 are both within the orthographic projection of the source electrode 11 on the substrate 100, i.e., the source electrode 11 covers the first gate electrode 131 and the second gate electrode 132. Besides, the orthographic projection of the first gate electrode 131 and the orthographic projection of the second gate electrode 132 on the substrate 100 are both within the orthographic projection of the drain electrode 14 on the substrate 100 as well, i.e., the drain electrode 14 covers the first gate electrode 131 and the second gate electrode 132. In some embodiments, the orthographic projection of the source electrode 11 and the orthographic projection of the drain electrode 14 on the substrate 100 overlap.

Optionally, as shown in FIG. 1 and FIG. 3, in an embodiment of the present application, the first semiconductor layer 121 or the second semiconductor layer 122 has a column-shaped cross-section in the direction which is perpendicular to the substrate 100; or the first semiconductor layer 121 or the second semiconductor layer 122 has a cross-section in a U shape in the direction which is perpendicular to the substrate 100, an opening of the U shape faces away from the first gate electrode 131, and the second gate electrode 132 with a column-shaped cross-section is disposed in the opening of the U shape.

Optionally, as shown in FIG. 3, the first semiconductor layer 121 and the second semiconductor layer 122 both have column-shaped cross-sections in the direction which is perpendicular to the substrate 100. By providing the second semiconductor layer 122 with a column-shaped cross-section, the facing area between the second gate electrode 132 and the second semiconductor layer 122 is increased, enabling an increase in the influence of the electric field applied by the second gate electrode 132 on the second semiconductor layer 122, and a further improvement of an on-state current of the vertical transistor 10.

Optionally, as shown in FIG. 1, the first semiconductor layer 121 and the second semiconductor layer 122 both have U-shaped cross-sections in the direction which is perpendicular to the substrate 100, such that the difficulty in manufacturing the semiconductor layer 12 is reduced, and the manufacturing cost of the vertical transistor 10 is further reduced. As shown in FIG. 1, the opening of the U shape faces away from the first gate electrode 131, and the second gate electrode 132 with a column-shaped cross-section is disposed in the opening of the U shape. In some embodiments, the second gate electrode 132 in the U-shaped trench is formed through full coating and etching processes.

Optionally, as shown in FIG. 1 and FIG. 3, in an embodiment of the present application, an orthographic projection of the first semiconductor layer 121 and an orthographic projection of the second semiconductor layer 122 on the substrate 100 are within the orthographic projection of the source electrode 11 on the substrate 100; and the orthographic projection of the first semiconductor layer 121 and the orthographic projection of the second semiconductor layer 122 on the substrate 100 are within the orthographic projection of the drain electrode 14 on the substrate 100.

Optionally, as shown in FIG. 1 and FIG. 3, the projection of the first semiconductor layer 121 and the projection of the second semiconductor layer 122 on the substrate 100 are within the projection of the source electrode 11 on the substrate 100. That is, the source electrode 11 covers the first semiconductor layer 121 and the second semiconductor layer 122.

Optionally, as shown in FIG. 1 and FIG. 3, the projection of the first semiconductor layer 121 and the projection of the second semiconductor layer 122 on the substrate 100 are within the projection of the drain electrode 14 on the substrate 100. That is, the drain electrode 14 covers the first semiconductor layer 121 and the second semiconductor layer 122 as well.

Optionally, as shown in FIG. 1 and FIG. 3, in an embodiment of the present application, the orthographic projection of the first semiconductor layer 121 and the orthographic projection of the second semiconductor layer 122 on the substrate 100 are separated from each other.

Optionally, as shown in FIG. 1 and FIG. 3, the first semiconductor layer 121 and the second semiconductor layer 122 are spaced apart from each other in the second direction parallel to the substrate 100, and the projection of the first semiconductor layer 121 and the projection of the second semiconductor layer 122 on the substrate 100 have no overlapping area, i.e., the first semiconductor layer 121 and the second semiconductor layer 122 have no overlapping portion in the first direction, such that the first semiconductor layer 121 is not connected to the second semiconductor layer 122.

Optionally, as shown in FIG. 1 and FIG. 3, in an embodiment of the present application, cross-sections of the first semiconductor layer 121 and the second semiconductor layer 122 in the first direction are symmetrically distributed about a center line of the gate electrode 13.

In the embodiments of the present application, as shown in FIG. 1 and FIG. 3, the longitudinal center line of the gate electrode 13 in the vertical transistor 10 is also a longitudinal center line of the vertical transistor 10.

The first semiconductor layer 121 and the second semiconductor layer 122 are symmetrically distributed about the longitudinal center line of the gate electrode 13, such that in the case that the first gate electrode 131 applies electric fields to the first semiconductor layer 121 and the second semiconductor layer 122, the electric field intensities at the first semiconductor layer 121 and at the second semiconductor layer 122 are the same, ensuring the currents flowing through the first semiconductor layer 121 and the second semiconductor layer 122 to have the same magnitude, such that the first semiconductor layer 121 and the second semiconductor layer 122 have the same loss rate, avoiding the problem that the service life of the vertical transistor 10 is shortened due to different loss rates of the first semiconductor layer 121 and the second semiconductor layer 122.

Optionally, as shown in FIG. 3, in an embodiment of the present application, the first gate insulating layer 151 conforms to a circumferential wall of a chamber enclosed by the source electrode 11, an inner sidewall of the first semiconductor layer 121, an inner sidewall of the second semiconductor layer 122, and the drain electrode 14; and the second gate insulating layer 152 conforms to a circumferential wall of a groove enclosed by the source electrode 11, an outer sidewall of the first semiconductor layer 121, an outer sidewall of the second semiconductor layer 122, and the drain electrode 14.

As shown in FIG. 3, the first gate electrode 131 is arranged in the chamber enclosed by the first gate insulating layer 151, such that the first gate electrode 131 is insulated from the semiconductor layer 12, the source electrode 11, and the drain electrode 14. The second gate electrode 132 is disposed in the groove enclosed by the second gate insulating layer 152, such that the second gate electrode 132 is insulated from the semiconductor layer 12, the source electrode 11, and the drain electrode 14.

Optionally, as shown in FIG. 3, in an embodiment of the present application, orthographic projections of outer contours of the source electrode 11 and the drain electrode 14 on the substrate 100 enclose orthographic projections of outer contours of the first semiconductor layer 121, the second semiconductor layer 122, and the first gate electrode 131 on the substrate 100, such that the source electrode 11 and the drain electrode 14 protrude outwards relative to the first gate electrode 131. As shown in FIG. 3, a sectional pattern formed by the source electrode 11, the first semiconductor layer 121, the second semiconductor layer 122, the first gate electrode 131, and the drain electrode 14 in combination is I-shaped.

As shown in FIG. 1 and FIG. 3, the orthographic projections of the outer contours of the source electrode 11 and the drain electrode 14 on the substrate 100 overlap with an orthographic projection of an outer contour of a second sub-gate electrode 132 on the substrate 100, such that outer sidewalls of the source electrode 11 and the drain electrode 14 are flush with an outer sidewall of the second sub-gate electrode 132.

It should be noted that, in the embodiments of the present application, “outer” and “inner” are mentioned with respect to the center of the vertical transistor 10, where the inner side is close to the center of the vertical transistor 10, and the outer side is away from the center of the vertical transistor 10.

Optionally, as shown in FIG. 1 and FIG. 3, in an embodiment of the present application, a portion of a bit line 20 disposed below the vertical transistor 10 is directly connected to the source electrode 11 and close to the first semiconductor layer 121 or the second semiconductor layer 122. The source electrode 11 is made of a doped semiconductor material. In some embodiments, the conductivity of the source electrode 11 is smaller than that of the bit line 20, such that in the case that the vertical transistor 10 shown in FIG. 1 and FIG. 3 is in an on state, the currents of the first semiconductor layer 121 and the second semiconductor layer 122 will directly flow to the nearest bit line 20, which reduces the mutual influence of the currents flowing through the first semiconductor layer 121 and the second semiconductor layer 122, and in this case, each vertical transistor 10 is equivalent to two sub-transistors in parallel. Therefore, the source electrode of the sub-transistor is not isolated physically, which simplifies the manufacturing process of the thin-film transistor, and reduces the manufacturing cost of the thin-film transistor.

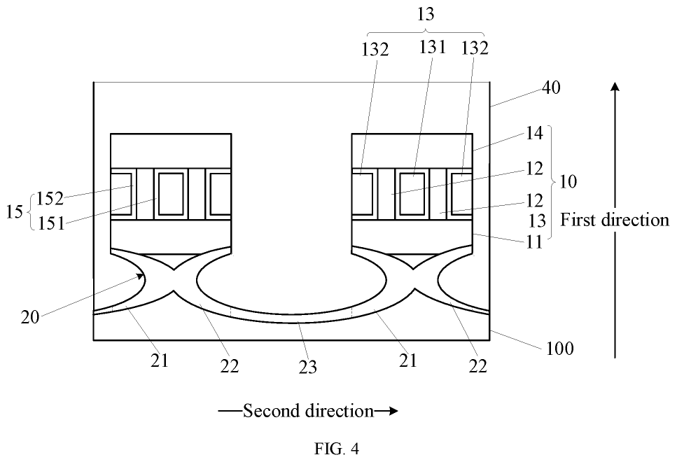

Based on the same inventive concept, the embodiments of the present application provide a memory cell, as shown in FIG. 4. The memory cell includes: a word line, a bit line 20, and a vertical transistor 10. In some embodiments, the vertical transistor 10 is one defined in any one of the embodiments described above.

In the embodiments of the present application, the bit line 20 is disposed at a side, away from a drain electrode 14, of a source electrode 11 of the vertical transistor 10 and is connected to the source electrode 11; the word line is connected to a gate electrode 13 of the vertical transistor 10; the drain electrode 14 and the source electrode 11 are stacked together, the vertical transistor 10 includes a semiconductor layer 12 in the same layer as the gate electrode 13, and the gate electrode 13 and the semiconductor layer 12 are both disposed between the source electrode 11 and the drain electrode 14 in a first direction which is perpendicular to a substrate; the gate electrode 13 includes at least a column-shaped first gate electrode 131 extending in the first direction; and the semiconductor layer 12 includes a first semiconductor layer 121 and a second semiconductor layer 122 in the same layer and spaced apart from each other, and the first gate electrode 131 is disposed between the first semiconductor layer 121 and the second semiconductor layer 122.

In the embodiments of the present application, as shown in FIG. 4, the bit line 20 includes a first portion 21 and a second portion 22 connected to each other, an orthographic projection of the first portion 21 and an orthographic projection of the first semiconductor layer 121 of the vertical transistor 10 on the substrate 100 have an overlapping area, and the orthographic projection of the first portion 21 and an orthographic projection of the second semiconductor layer 122 of the vertical transistor 10 on the substrate 100 are separated from each other; and an orthographic projection of the second portion 22 and the orthographic projection of the first semiconductor layer 121 on the substrate 100 are separated from each other, and the orthographic projection of the second portion 22 and the orthographic projection of the second semiconductor layer 122 on the substrate 100 have an overlapping area.

Optionally, as shown in FIG. 4, two symmetrically arranged vertical transistors 10 as defined in the embodiments of the present application are illustrated, and the memory cell further includes the bit line 20 which is disposed between the source electrode 11 of the vertical transistor 10 and the substrate 100. The memory cell further includes the word line connected to the gate electrode 13 of the vertical transistor 10, which is hidden from the longitudinal cross-sectional diagram and thus not described. In some embodiments, as shown in FIG. 4, an extending direction of the bit line 20 is parallel to a second direction, and an extending direction of the word line is parallel to the substrate 100 and perpendicular to the second direction.

As shown in FIG. 4, the bit line 20 includes the first portion 21 and the second portion 22 connected to each other. The first portion 21 is disposed below the first semiconductor layer 121 of the vertical transistor 10, the projection of the first portion 21 and the projection of the first semiconductor layer 121 on the substrate 100 have an overlapping area, and the projection of the first portion 21 and the projection of the second semiconductor layer 122 of the vertical transistor 10 on the substrate 100 have no overlapping area, such that it is ensured that a current flows through the first portion 21 and the first semiconductor layer 121. The second portion 22 is disposed below the second semiconductor layer 122, the projection of the second portion 22 and the projection of the second semiconductor layer 122 on the substrate 100 have an overlapping area, and the projection of the second portion 22 and the projection of the first semiconductor layer 121 on the substrate have no overlapping area, such that it is ensured that a current flows through the second portion 22 and the second semiconductor layer 122.

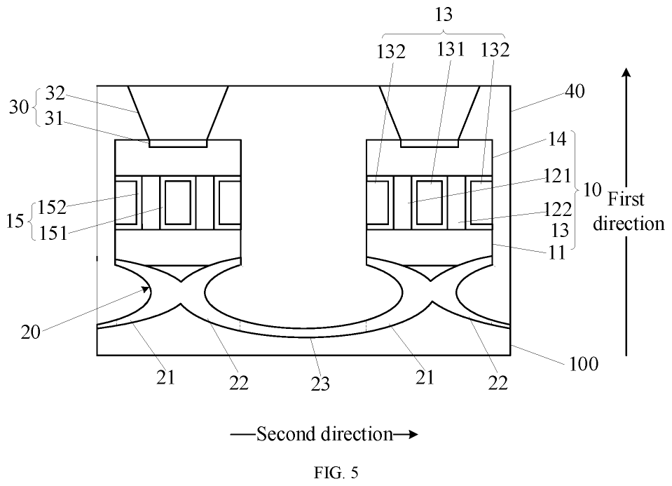

In the embodiments of the present application, a plurality of vertical transistors 10 are included, which are arranged in an array. The vertical transistors 10 in the same row are connected to the same bit line 20, as shown in FIG. 4 and FIG. 5, where the two vertical transistors 10 in the second direction are in the same row. The vertical transistors 10 in the same column are connected to the same word line.

In the embodiments of the present application, the word line extends in a direction parallel to the substrate 100, and the extending direction of the word line is perpendicular to the extending direction of the bit line 20. FIG. 4 and FIG. 5 show schematic cross-sectional structural diagrams in the extending direction of the bit line 20, and the word line is not shown in FIG. 4 and FIG. 5 due to the shielding of the vertical transistor 10.

Optionally, the bit line 20 is arranged as a buried line. In some embodiments, the word line is arranged as a filled line.

As the memory cell according to the embodiments of the present application includes the vertical transistor 10 as defined in any one of the embodiments described above, the principles and technical effects of the memory cell are found with reference to the foregoing embodiments, which are not repeated herein.

Optionally, the bit line 20 is made of metal silicide, and the source electrode 11 is made of doped silicon.

In the embodiments of the present application, the bit line 20 is made of metal silicide, and the source electrode 11 is made of doped silicon, such that the conductivity of the bit line 20 is greater than that of the source electrode 11, and thus in the case that the vertical transistor 10 is in an on state, the current of the first semiconductor layer 121 will directly flow to the first portion 21 of the nearest bit line 20, and the current of the second semiconductor layer 122 will directly flow to the second portion 22 of the nearest bit line 20, which reduces crosstalk of the currents flowing through the first semiconductor layer 121 and the second semiconductor layer 122.

Optionally, in an embodiment of the present application, the gate electrode 13 further includes a second gate electrode 132. The second gate electrode 132 is connected to the first gate electrode 131, and the second gate electrode 132 is arranged around outer side surfaces of the first semiconductor layer 121 and the second semiconductor layer 122; or the second gate electrode 132 is arranged at an outer side surface of the first semiconductor layer 131 and/or an outer side surface of the second semiconductor layer 132.

Optionally, as shown in FIG. 4 and FIG. 5, in an embodiment of the present application, the bit line 20 further includes a third portion 23 with one end connected to the first portion 21 and the other end connected to the second portion 22; and the orthographic projection of the first semiconductor layer 121 and the orthographic projection of the second semiconductor layer 122 on the substrate 100 are both separated from an orthographic projection of the third portion 23 on the substrate 100.

In the embodiments of the present application, as shown in FIG. 4 and FIG. 5, the bit line 20 includes the first portion 21, the second portion 22, and the third portion 23 connected sequentially in the first direction. One end of the third portion 23 is connected to the second portion 22 disposed below the second semiconductor layer 122 in one vertical transistor 10, and the other end is connected to the first portion 21 disposed below the first semiconductor layer 121 in another adjacent vertical transistor 10.

It should be noted that, as shown in FIG. 4 and FIG. 5, boundaries among the first portion 21, the second portion 22, and the third portion 23 are indicated by the dotted lines. However, in a real product, the first portion 21, the second portion 22, and the third portion 23 are manufactured together, without the dotted lines therebetween shown in FIG. 4 and FIG. 5.

Optionally, in an embodiment of the present application, a first sub-gate electrode 131 and a second sub-gate electrode 132 are both connected to the word line, such that the word line can apply levels to the first sub-gate electrode 131 and the second sub-gate electrode 132 simultaneously, which further enhances the electric field intensity at the gate electrode 13, enabling an improvement of an on-state current of the vertical transistor 10, resulting in an improvement of the driving capability and the turn-on speed of the vertical transistor 10, and a further improvement of the performance of the memory cell.

Optionally, as shown in FIG. 5, the memory cell further includes a connection structure 30. In some embodiments, the vertical transistor 10 and the connection structure 30 are stacked together in the first direction, as shown in FIG. 5, where the connection structure 30 is arranged at a side, away from the source electrode 11, of the drain electrode 14 of the vertical transistor 10.

In the embodiments of the present application, the connection structure 30 is configured to electrically connect the transistor 10 to other devices of the memory cell, for example, to electrically connect the vertical transistor 10 to a capacitor, or to electrically connect the vertical transistor 10 to magnetic tunnel junctions (MTJ).

In the embodiments of the present application, the connection structure 30 facilitates another device, which is to be electrically connected to the vertical transistor 10, to be formed at a side of the connection structure 30 directly, such that after the vertical transistor 10 and the connection structure 30 are formed, a capacitor or an MTJ is selectively formed at the side of the connection structure 30 as needed, or after the bit line 20, the vertical transistor 10, the word line, and the connection structure 30 are sequentially formed at a side of the substrate 100 by using one production line, a capacitor or an MTJ is formed by using another production line, such that the production efficiency of the memory cell is improved.

Optionally, as shown in FIG. 5, the connection structure 30 includes a silicide structure 31 and a metal structure 32. As the drain electrode 14 is mostly made of a doped semiconductor material, there is a significant difference in conductivity between the drain electrode and the metal structure 32. The silicide structure 31 reduces the interface resistance between the metal structure 32 and the drain electrode 14, such that the performance of the memory cell is ensured.

Based on the same inventive concept, the embodiments of the present application provide an electronic device. The electronic device includes any one of the memories as defined in the embodiments described above.

In the embodiments of the present application, as the electronic device employs any one of the memories as defined in the foregoing embodiments, reference is made to the foregoing embodiments for the principles and technical effects, which are not repeated herein.

In some embodiments, the electronic device includes a smart phone, a computer, a tablet, an artificial intelligence device, a wearable device, or a portable power source.

It should be noted that the electronic device is not limited to those described above, and a person skilled in the art may provide, in various devices, any one of the memories as defined in the above embodiments of the present application according to practical application needs, so as to acquire the electronic device as defined in the embodiments of the present application.

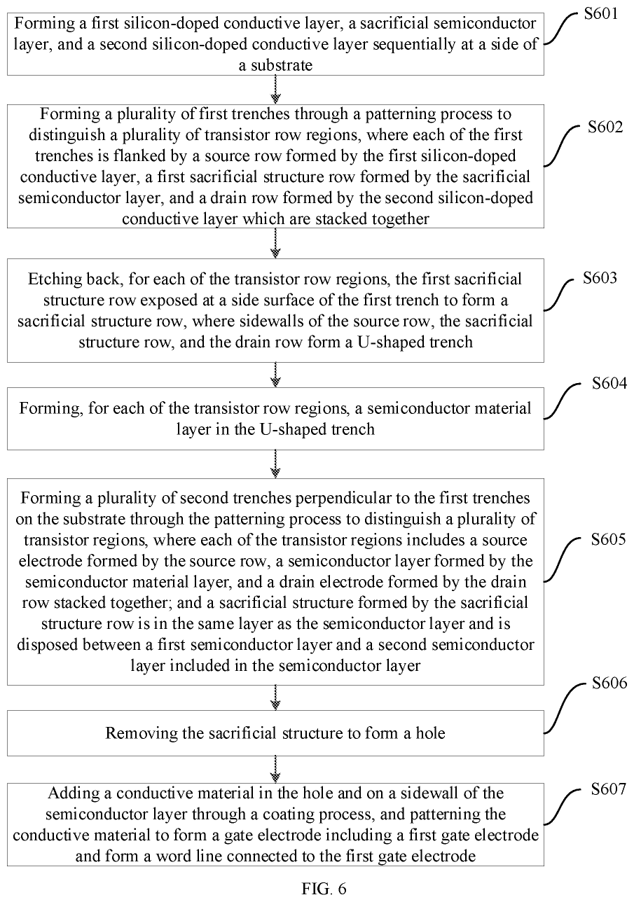

Based on the same inventive concept, the embodiments of the present application provide a method for manufacturing a memory cell. The flowchart of the method is shown in FIG. 6. The method includes the following steps S601-S607:
In S601, a first silicon-doped conductive layer, a sacrificial semiconductor layer, and a second silicon-doped conductive layer are formed sequentially at a side of a substrate.
In S602, a plurality of first trenches are formed through a patterning process to distinguish a plurality of transistor row regions, where each of the first trenches is flanked by a source row formed by the first silicon-doped conductive layer, a first sacrificial structure row formed by the sacrificial semiconductor layer, and a drain row formed by the second silicon-doped conductive layer which are stacked together.
In S603, for each of the transistor row regions, the first sacrificial structure row exposed at a side surface of the first trench is etched back to form a sacrificial structure row, where sidewalls of the source row, the sacrificial structure row, and the drain row form a U-shaped trench.
In S604, for each of the transistor row regions, a semiconductor material layer is formed in the U-shaped trench.
In S605, a plurality of second trenches perpendicular to the first trenches are formed on the substrate through the patterning process to distinguish a plurality of transistor regions, where each of the transistor regions includes a source electrode formed by the source row, a semiconductor layer formed by the semiconductor material layer, and a drain electrode formed by the drain row stacked together; and a sacrificial structure formed by the sacrificial structure row is in the same layer as the semiconductor layer and is disposed between a first semiconductor layer and a second semiconductor layer included in the semiconductor layer.
In S606, the sacrificial structure is removed to form a hole.
In S607, a conductive material is filled in the hole and on a sidewall of the semiconductor layer through a coating process, and the conductive material is patterned to form a gate electrode including a first gate electrode and form a word line connected to the first gate electrode.

In the method for manufacturing a vertical transistor according to the embodiments of the present application, the sacrificial semiconductor layer is arranged, and the sacrificial structure is formed based on the sacrificial semiconductor layer in the manufacturing process, such that the first semiconductor layer and the second semiconductor layer are formed, which are disposed at two sides of the sacrificial structure. After the sacrificial structure is removed, the gate electrode is formed, which is at least partially disposed between the first semiconductor layer and the second semiconductor layer, such that the gate electrode can drive the first semiconductor layer and the second semiconductor layer simultaneously, enabling an improvement of an on-state current of the vertical transistor and a further improvement of the performance of the vertical transistor.

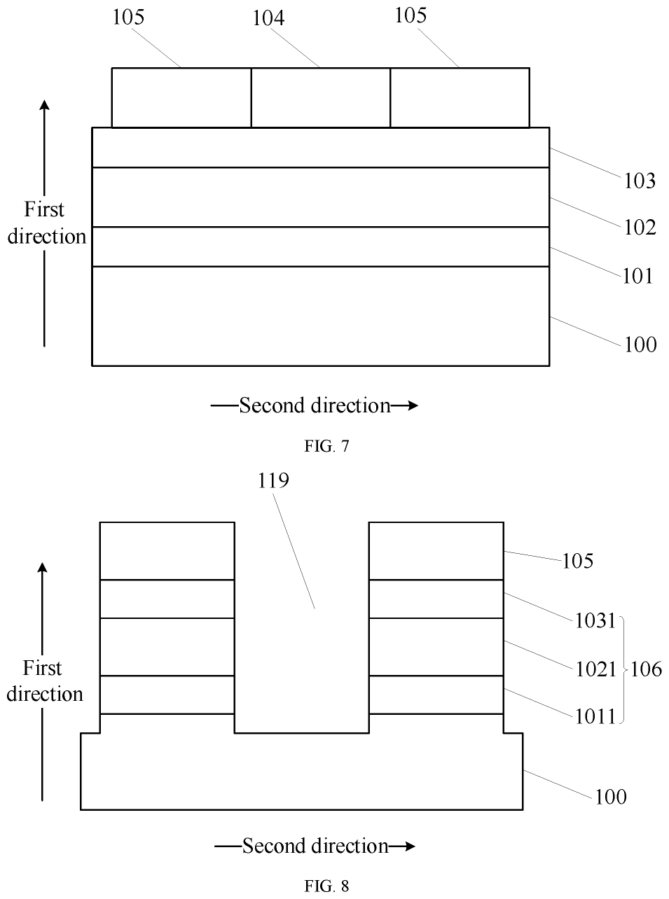

In order to facilitate the reader to intuitively understand the advantages of the method for manufacturing the two memories as well as the memories manufactured by the method according to the embodiments of the present application, the following specific description will be made with reference to FIG. 7 to FIG. 22.

In the embodiments of the present application, the step S601 specifically includes: forming the first silicon-doped conductive layer 101, the sacrificial semiconductor layer 102, and the second silicon-doped conductive layer 103 sequentially at the side of the substrate 100, then forming a first photoresist structure 104 at a side of the second silicon-doped conductive layer 103 away from the substrate 100, and forming a first mask structure 105 at two sidewalls of the first photoresist structure 104, as shown in FIG. 7.

Optionally, the film layer structures can be manufactured by using chemical vapor deposition (CVD), physical vapor deposition (PVD), atomic layer deposition (ALD), and other deposition processes.

Optionally, the first silicon-doped conductive layer 101 and the second silicon-doped conductive layer 103 are made of doped semiconductor materials. In some embodiments, both the first silicon-doped conductive layer 101 and the second silicon-doped conductive layer 103 are subjected to N-type doping. The doping degree is determined based on a specific manufacturing process or requirement. In some embodiments, the first silicon-doped conductive layer 101 is lightly doped; the sacrificial layer 102 is silicon germanium (GeSi); and the manufacturing material for the first mask structure 105 is silicon oxide.

Optionally, in the embodiments of the present application, the first silicon-doped conductive layer 101, the sacrificial semiconductor layer 102, and the second silicon-doped conductive layer 103 are formed by using an epitaxial growth process. Therefore, the thicknesses of the film layers, especially the thickness of the sacrificial semiconductor layer 102, are accurately controlled, such that the sizes of the semiconductor layer 12 and the gate electrode 13 acquired in subsequent manufacturing are accurately controlled, ensuring the manufacturing accuracy of the vertical transistor, and thus ensuring the uniformity of transistor performance in the memory cells in the memory, and further ensuring the performance of the memory.

In the embodiments of the present application, the step S602 specifically includes: removing the first photoresist structure 104, and etching, with the first mask structure 105 as a mask, the second silicon-doped conductive layer 103, the sacrificial semiconductor layer 102, the first silicon-doped conductive layer 101, and a portion of the substrate 100 to form the plurality of first trenches 119 through the patterning process to distinguish the plurality of transistor row regions, where each of the first trenches 119 is flanked by the source row 1011 formed by the first silicon-doped conductive layer 101, the first sacrificial structure row 1021 formed by the sacrificial semiconductor layer 102, and the drain row 1031 formed by the second silicon-doped conductive layer 103 stacked together, as shown in FIG. 8, where the transistor row regions each include an initial stacked structure row 106.

In the embodiments of the present application, the first mask structure 105 is a hard mask which enables self-alignment in etching the second silicon-doped conductive layer 103, the sacrificial semiconductor layer 102, the first silicon-doped conductive layer 101, and the portion of the substrate 100, such that the etching accuracy is ensured.

Optionally, as can be seen from FIG. 8, the initial stacked structure row 106 extends in a third direction, which is parallel to the substrate 100 and perpendicular to a second direction. The second direction is an extending direction of a bit line 20 acquired in subsequent manufacturing. The plurality of initial stacked structure rows 106 are spaced apart from each other in the second direction. As shown in FIG. 8, the initial stacked structure row 106 includes the source row 1011, the first sacrificial structure row 1021, and the drain row 1031 stacked together.

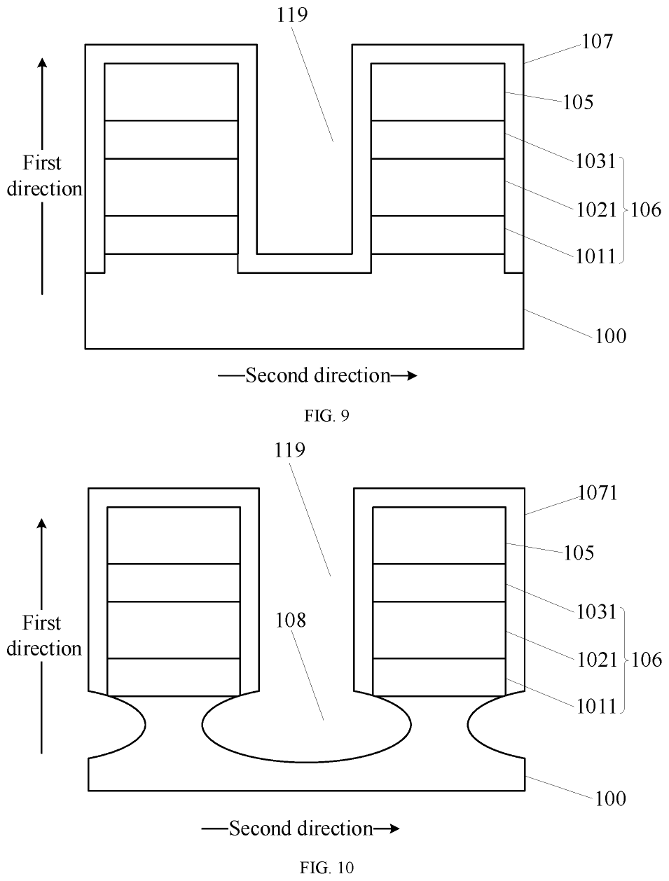

Optionally, after the step S602, the method further includes: forming a protection layer 107 that covers top and side walls of the initial stacked structure row 106, as shown in FIG. 9, where the protection layer 107 is an integral layer that further covers the substrate 100 between two adjacent initial stacked structure rows 106. In some embodiments, the manufacturing material for the protection layer 107 includes silicon oxide.

Next, the portion of the substrate 100 between the two adjacent initial stacked structure rows 106 is etched along the first trench 119 to form an arc-shaped slot 108 extending below at least a portion of the two initial stacked structure rows 106, as shown in FIG. 10, where the arc-shaped slot 108 is communicated with the first trench 119.

As shown in FIG. 10, the protection layer 107 and the portion of the substrate 100 between the two adjacent initial stacked structure rows 106 are etched to form the arc-shaped slot 108, and the protection layer 107 is etched to form a protection structure 1071.

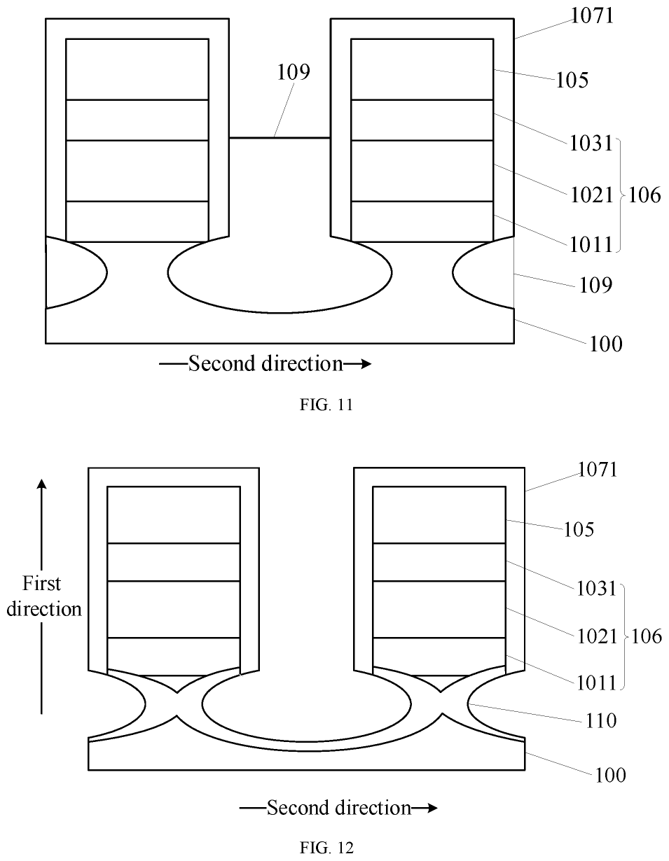

Then, a metal material, such as titanium or cobalt, is filled into the arc-shaped slot 108 and between the two adjacent initial stacked structure rows 106 to form a metal layer 109, as shown in FIG. 11, where the arc-shaped slot 108 is full with the metal layer 109, and an upper surface of the metal layer 109 is flush with an upper surface of the first sacrificial structure row 1021 of the initial stacked structure row 106.

Next, the metal layer 109 is treated by using an annealing process, such that the metal layer 109 reacts with a portion of the substrate 100 to form an initial bit line layer 110 including metal silicide, and then an unreacted portion of the metal layer 109 is removed, as shown in FIG. 12, where the initial bit line layer 110 conforms to the arc-shaped slot 108 and is connected to the source row 1011.

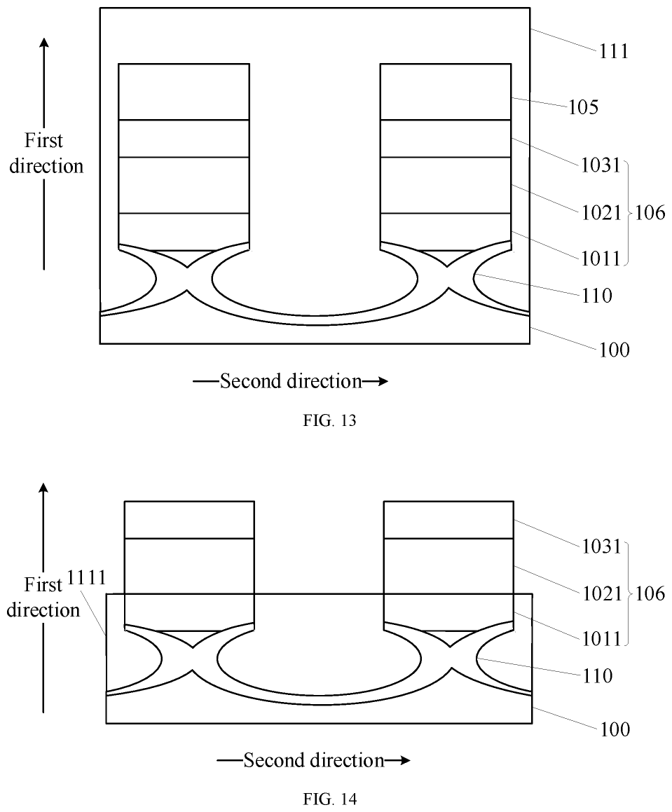

Then, a dielectric material, such as silicon oxide, is deposited by using a deposition process and then treated by using a chemical mechanical polishing (CMP) process to form a first planarization layer 111, as shown in FIG. 13. In some embodiments, the protection structure 1071 and the first planarization layer 111 are made of the same material, and thus both are represented by the first planarization layer 111 in FIG. 13, and the protection structure 1071 is not shown in FIG. 13.

Next, a portion of the first planarization layer 111 and the first mask structure 105 are removed by using an etching process to form a first planarization structure 1111, as shown in FIG. 14, where an upper surface of the first planarization structure 1111 is flush with an upper surface of the source row 1011, such that two sidewalls of the first sacrificial structure row 1021 are exposed.

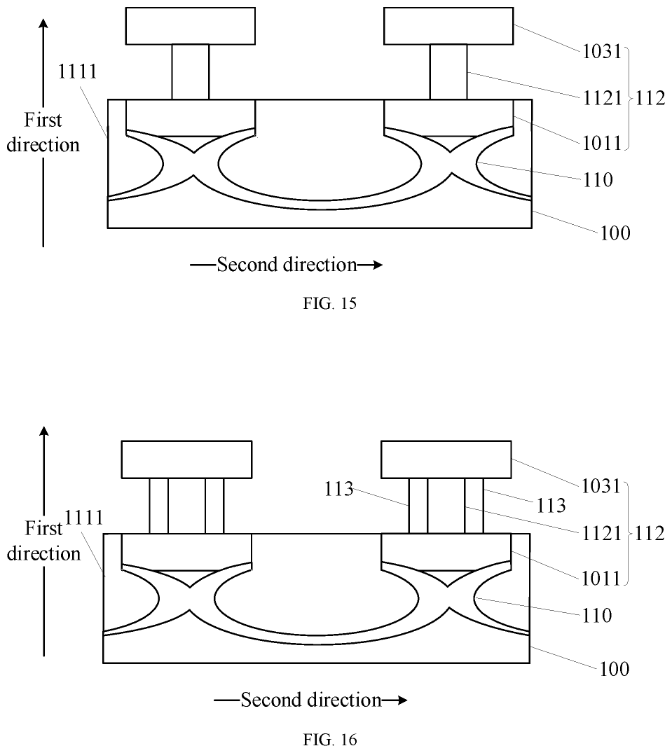

In the embodiments of the present application, the step S603 specifically includes: etching back, for each of the transistor row regions, the first sacrificial structure row 1021 exposed at the side surface of the first trench 119 to form the sacrificial structure row 1121, where the sidewalls of the source row 1011, the sacrificial structure row 1121, and the drain row 1031 form the U-shaped trench, as shown in FIG. 15.

Optionally, the first sacrificial structure row 1021 is laterally etched by using a selective etching process to form a sacrificial semiconductor material layer 1121, such that two sidewalls of the sacrificial semiconductor material layer 1121 are both recessed relative to the source row 1011 and the drain row 1031, resulting in a stacked structure row 112, as shown in FIG. 15, where the stacked structure row 112 includes the source row 1011, the sacrificial semiconductor material layer 1121, and the drain row 1031 stacked together.

In the embodiments of the present application, in the step S604, forming the semiconductor material layer in the U-shaped trench for each of the transistor row regions specifically includes: forming a target semiconductor layer at exposed surfaces of the source row 1011, the sacrificial semiconductor material layer 1121, and the drain row 1031 by using an epitaxial process; and removing a portion of the semiconductor layer by using the etching process to form the semiconductor material layer 113 disposed at two outer sidewalls of the sacrificial semiconductor material layer 1121, as shown in FIG. 16.

As the source row 1011, the sacrificial semiconductor material layer 1121, and the drain row 1031 are all formed based on the epitaxial process, the epitaxial process can be continuously used to form the target semiconductor layer that conforms to the surfaces of the source row 1011, the sacrificial semiconductor material layer 1121, and the drain row 1031; and the film layer thickness of the target semiconductor layer is accurately controlled, enabling an improvement of the control accuracy upon film layer formation of the semiconductor material layer 113.

Optionally, after the step S604, the method further includes the following steps:

First, a mask structure 115 is formed at a side of the stacked structure row 112 away from the substrate 100. An extending direction of the mask structure 115 is perpendicular to an extending direction of the stacked structure row.

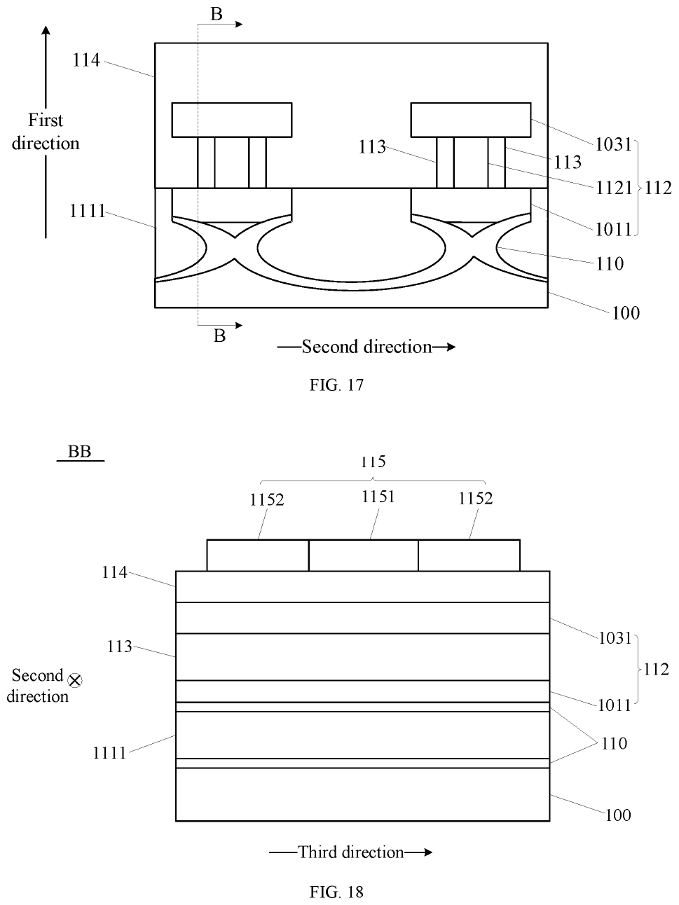

Optionally, a dielectric material, such as silicon oxide, is deposited by using the deposition process and then treated by using a CMP process to form a second planarization layer 114, as shown in FIG. 17. Next, the mask structure 115 is formed at a side of the second planarization layer 114 away from the substrate 100, as shown in FIG. 18. In the embodiments of the present application, FIG. 7 to FIG. 17 are schematic cross-sectional structural diagrams in a first direction, which is perpendicular to the second direction; and FIG. 18 is a schematic cross-sectional structural diagram along the BB direction illustrating a mask structure prepared from the structure shown in FIG. 17, and the first direction is denoted by® in FIG. 18, which indicates that the first direction is perpendicular to the paper and extends into the paper.

As shown in FIG. 18, the mask structure 115 includes a first sub-mask structure 1151 and a second sub-mask structure 1152 disposed at two sidewalls of the first sub-mask structure 1151. In some embodiments, the first sub-mask structure 1151 is made of a photoresist material, and the second sub-mask structure 1152 is made of a silicon oxide material, i.e., the second sub-mask structure 1152 is a hard mask, which facilitates a subsequent self-aligned etching process.

In the embodiments of the present application, in the step S605, the plurality of second trenches 120 perpendicular to the first trenches 119 are formed on the substrate 100 through the patterning process to distinguish the plurality of transistor regions, where each of the transistor regions includes the source electrode 11 formed by the source row 1011, the semiconductor layer 12 formed by the semiconductor material layer 113, and the drain electrode 14 formed by the drain row 1031 stacked together; and the sacrificial structure formed by the sacrificial structure row 1121 is in the same layer as the semiconductor layer 12 and is disposed between the first semiconductor layer 121 and the second semiconductor layer 122 included in the semiconductor layer 12.

Optionally, the stacked structure row 112, the semiconductor material layer 113, and the initial bit line layer 110 are etched based on the mask structure 115 by using the self-aligned etching process. The plurality of second trenches with an extending direction which is perpendicular to that of the first trenches are formed on the substrate 100 by using the patterning process, such that each of the transistor row regions is divided into the plurality of transistor regions. Each of the second trenches is flanked by a stacked structure 116 formed by the stacked structure row 112, the semiconductor layer 12 formed by the semiconductor material layer 113, and the bit line 20 formed by the initial bit line layer 110 stacked together.

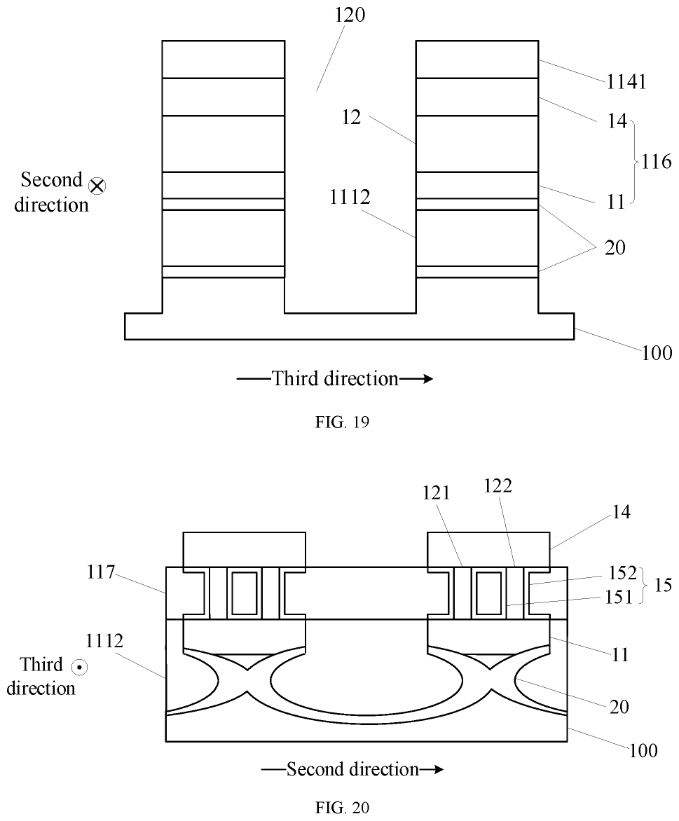

Optionally, the first sub-mask structure 1151 is removed, and the stacked structure row 112, the semiconductor material layer 113, and the initial bit line layer 110 are etched with the second sub-mask structure 1152 as a mask, resulting in a plurality of stacked structures 116, the semiconductor layers 12, and the bit lines 20 spaced apart from each other, respectively, as shown in FIG. 19.

In the embodiments of the present application, the second sub-mask structure 1152 is a hard mask which enables self-alignment in etching the stacked structure row 112, the semiconductor material layer 113, and the initial bit line layer 110, such that the etching accuracy is ensured.

As shown in FIG. 19, the stacked structure 116 includes the source electrode 11 and the drain electrode 14. The sacrificial structure formed by etching the sacrificial semiconductor row 1121 is invisible due to the shielding of the semiconductor layer 12. The source electrode 11 is connected to the bit line 20. The second planarization layer 114 is etched to form a second planarization structure 1141, and the first planarization structure 1111 is etched to form a third planarization structure 1112. FIG. 19 is a schematic cross-sectional structural diagram in the second direction, and the first direction is denoted by® in FIG. 19, which indicates that the first direction is perpendicular to the paper and extends into the paper.

In the embodiments of the present application, in the step S606, removing the sacrificial structure to form the hole includes: removing the second planarization structure 1141 and a sacrificial semiconductor structure 1121.

In the embodiments of the present application, after the step S606, the method further includes: forming a first gate insulating layer 151 that conforms to a circumferential wall of a chamber enclosed by the source electrode 11, an inner sidewall of the first semiconductor layer 121, an inner sidewall of the second semiconductor layer 122, and the drain electrode 14; and a second gate insulating layer 152 that conforms to a circumferential wall of a groove enclosed by the source electrode 11, an outer sidewall of the first semiconductor layer 121, an outer sidewall of the second semiconductor layer 122, and the drain electrode 14 by using the deposition process, resulting in a gate insulating layer 15, such that the gate electrode 13 to be manufactured subsequently is insulated from the source electrode 11, the drain electrode 14, the first semiconductor layer 121, and the second semiconductor layer 122.

In the embodiments of the present application, in the step S607, adding the conductive material in the hole and the sidewall of the semiconductor layer 12 through the coating process and patterning the conductive material to form the gate electrode 13 including the first gate electrode 131 and form the word line connected to the first gate electrode 131 specifically includes the following steps:

First, a metal material is deposited by using the atomic layer deposition process, such that the metal material fills the chamber enclosed by the first gate insulating layer 151 and fills the groove enclosed by the second gate insulating layer 152 to form an initial word line layer 117, as shown in FIG. 20. FIG. 20 is a schematic cross-sectional structural diagram in the first direction, and the second direction is denoted by @ in FIG. 20, which indicates that the second direction is perpendicular to the paper and extends out of the paper.

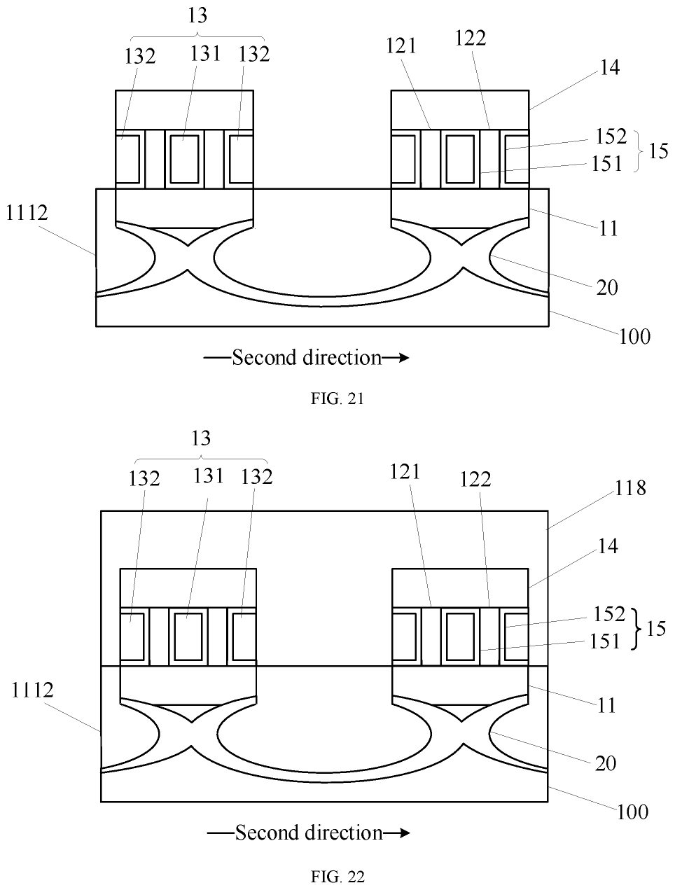

Then, the initial word line layer 117 is patterned to form a first sub-gate electrode 131 between adjacent first semiconductor layer 121 and second semiconductor layer 122 and a second sub-gate electrode 132 at outer sidewalls of the first semiconductor layer 121 and the second semiconductor layer 122, as shown in FIG. 21.

In the embodiments of the present application, the first sub-gate electrode 131 is arranged in the chamber enclosed by the first gate insulating layer 151, such that the first sub-gate electrode 131 is insulated from the first semiconductor layer 121, the second semiconductor layer 122, the source electrode 11, and the drain electrode 14. The second sub-gate electrode 132 is arranged in the groove enclosed by the second gate insulating layer 152, such that the second sub-gate electrode 132 is insulated from the first semiconductor layer 121, the source electrode 11, and the drain electrode 14, and such that the second sub-gate electrode 132 is insulated from the second semiconductor layer 122, the source electrode 11, and the drain electrode 14.

In the embodiments of the present application, both the first semiconductor layer 121 and the second semiconductor layer 122 are laterally recessed relative to outer contours of the source electrode 11 and the drain electrode 14, and the source electrode 11 and the drain electrode 14 are manufactured based on the epitaxial growth process, such that a distance between the source electrode 11 and the drain electrode 14 in the direction which is perpendicular to the substrate 100 is accurately controlled; and the gate insulating layer 15 is formed by using the ALD process, such that the thickness of the gate insulating layer 151 is accurately controlled. Therefore, the size of the chamber enclosed by the first gate insulating layer 151 and the size of the groove enclosed by the second gate insulating layer 152 are accurately controlled, such that the sizes of the first sub-gate electrode 131 and the second sub-gate electrode 132, especially the lengths of the first sub-gate electrode 131 and the second sub-gate electrode 132 are accurately controlled, which improves the manufacturing accuracy of the gate electrode 13, ensures the manufacturing accuracy of the vertical transistor 10, and further ensures the manufacturing accuracy of the memory cell, thus ensuring the uniformity of the performance of memory cells in the memory, and further ensuring the performance of the memory.

Optionally, the initial word line layer 117 is patterned by forming a self-leveling planarization layer at a side of the initial word line layer 117 by using a spin on hard (SOH) mask process, and then forming a photoresist structure at a side of the planarization layer and etching the initial word line layer 117 with the photoresist structure as a mask.

Next, a dielectric material, such as silicon oxide, is deposited by using the deposition process, and then planished to form a third dielectric layer 118, as shown in FIG. 22.

Then, the third dielectric layer 118 is patterned to form a dielectric structure 40 including an opening that exposes a portion of the drain electrode 14, and then a silicide structure 31 is formed at the exposed portion of the drain electrode 14. Then, a metal material is deposited to fill the opening and the silicide structure 31 to form a metal structure 32, such that a connection structure 30 is acquired, resulting in the structure shown in FIG. 5.

Optionally, a capacitor or an MTJ is manufactured at a side of the connection structure 30.

With the embodiments of the present application, at least the following beneficial effects can be achieved:

In the vertical transistor 10 according to the embodiments of the present application, the semiconductor layer 12 includes the first semiconductor layer 121 and the second semiconductor layer 122 spaced apart from each other. The first gate electrode 131 is disposed between the first semiconductor layer 121 and the second semiconductor layer 122, such that the first gate electrode 131 can apply electric fields to the first semiconductor layer 121 and the second semiconductor layer 122 simultaneously so as to drive the first semiconductor layer 121 and the second semiconductor layer 122 simultaneously, enabling an improvement of an on-state current of the vertical transistor 10 and a further improvement of the performance of the vertical transistor 10.

Those skilled in the art will understand that various steps, measures, and schemes in the operations, methods, and procedures discussed in the present application may be alternated, modified, combined, or deleted. Further, other steps, measures, and schemes in the operations, methods, and procedures discussed in the present application may also be alternated, modified, rearranged, split, combined, or deleted. Further, steps, measures, and schemes in the operations, methods, and procedures disclosed in the prior art and the present application may also be alternated, modified, rearranged, split, combined, or deleted.

In the descriptions of the present application, directional or positional relationships indicated by the words, such as “central”, “upper”, “lower”, “front”, “rear”, “left”, “right”, “vertical”, “horizontal”, “top”, “bottom”, “inner”, “outer”, based on exemplary directional or positional relationships shown in the accompanying drawings, are merely for convenience of description or a simplified description of the embodiments of the present application, and are not intended to indicate or imply that the referred apparatus or component must have a particular orientation or be constructed and operated in a particular orientation, and thus, are not to be construed as limiting the present application.

The terms “first” and “second” are used for descriptive purposes only and are not to be construed as indicating or implying relative importance or to implicitly indicate the number of technical features indicated. Thus, features defined as “first”, “second” etc., explicitly or implicitly include one or more of the features. In the descriptions of the present application, “a plurality” means two or more, unless otherwise specified.

In the description of the present application, it should be noted that unless otherwise explicitly specified or limited, the terms “mount,” “connect,” and “connection” shall be construed broadly and may be, for example, fixed connection, detachable connection, integrated connection, direct connection, indirect connection via an intermediate, or internal communication between two elements. For those of ordinary skill in the art, the specific meaning of the above terms in the present application may be understood according to the specific condition.

In the descriptions of the specification, the specific features, structures, materials, or characteristics may be combined in any suitable manner in any one or more embodiments or examples.

It should be understood that, although the steps in the flowcharts of the accompanying drawings are shown in order as indicated by the arrows, the steps are not necessarily performed in order as indicated by the arrows. In some implementations of the embodiments of the present application, the steps in the flowcharts may be performed in another order as needed, unless explicitly stated otherwise herein. Moreover, some or all of the steps in the flowcharts may include a plurality of sub-steps or a plurality of stages based on an actual implementation. Some or all of the sub-steps or stages may be performed at the same time, or may be performed at different times where the order of the sub-steps or stages may be flexibly configured as needed, which is not limited in the embodiments of the present application.

The foregoing is merely a part of the embodiments of the present application, and it should be noted that, for those skilled in the art, other similar implementations based on the technical idea of the present application may be adopted without departing from the technical concept of the present application and are covered by the embodiments of the present application.

1. A vertical transistor, comprising:
a source electrode disposed on a substrate;
a drain electrode which is disposed at a side, away from the substrate, of the source electrode; and
a gate electrode and a semiconductor layer, which are in the same layer, and are disposed between the source electrode and the drain electrode in a first direction which is perpendicular to the substrate,
wherein the gate electrode at least comprises a column-shaped first gate electrode extending in the first direction,
wherein the semiconductor layer comprises a first semiconductor layer and a second semiconductor layer which are in the same layer and spaced apart from each other, and
wherein the first gate electrode is disposed between the first semiconductor layer and the second semiconductor layer.

2. The vertical transistor according to claim 1, wherein the gate electrode further comprises a second gate electrode which is connected to the first gate electrode, wherein the second gate electrode is disposed around outer side surfaces of the first semiconductor layer and the second semiconductor layer.

3. The vertical transistor according to claim 1, wherein the gate electrode further comprises a second gate electrode disposed at one or more of an outer side surface of the first semiconductor layer and an outer side surface of the second semiconductor layer.

4. The vertical transistor according to claim 2, wherein both an orthographic projection of the first gate electrode on the substrate and an orthographic projection of the second gate electrode on the substrate are within an orthographic projection of one of the source electrode and the drain electrode on the substrate.

5. The vertical transistor according to claim 4, wherein one of the first semiconductor layer and the second semiconductor layer has a cross-section in one of a rectangular shape and a U shape in the first direction, wherein an opening of the cross-section in the U shape faces away from the first gate electrode, and the second gate electrode with a rectangular-shaped cross-section is disposed in the opening of the cross-section in the U shape.

6. The vertical transistor according to claim 1, wherein both an orthographic projection of the first semiconductor layer on the substrate and an orthographic projection of the second semiconductor layer on the substrate are within an orthographic projection of the source electrode on the substrate, and
both the orthographic projection of the first semiconductor layer on the substrate and the orthographic projection of the second semiconductor layer on the substrate are within an orthographic projection of the drain electrode on the substrate.

7. The vertical transistor according to claim 1, wherein an orthographic projection of the first semiconductor layer on the substrate and an orthographic projection of the second semiconductor layer on the substrate are separated from each other.

8. The vertical transistor according to claim 1, wherein cross-sections of the first semiconductor layer and the second semiconductor layer in the first direction are symmetrically distributed about a center line of the gate electrode.

9. A memory cell, comprising:
a word line;
a bit line; and
a vertical transistor,
wherein the bit line is disposed at a side, away from a drain electrode of the vertical transistor, of a source electrode of the vertical transistor, and the bit line is connected to the source electrode,
wherein the word line is connected to a gate electrode of the vertical transistor,
wherein a substrate of the vertical transistor is at a side, away from the drain electrode, of the bit line and the source electrode, wherein the vertical transistor comprises a semiconductor layer which is in the same layer as the gate electrode, and both the gate electrode and the semiconductor layer are disposed between the source electrode and the drain electrode in a first direction which is perpendicular to the substrate,
wherein the gate electrode at least comprises a column-shaped first gate electrode extending in the first direction, wherein the semiconductor layer comprises a first semiconductor layer and a second semiconductor layer which are in the same layer and spaced apart from each other, and the first gate electrode is disposed between the first semiconductor layer and the second semiconductor layer,
wherein the bit line comprises a first portion and a second portion which are connected to each other,
wherein an orthographic projection of the first portion on the substrate and an orthographic projection of the first semiconductor layer of the vertical transistor on the substrate have an overlapping area, and the orthographic projection of the first portion on the substrate and an orthographic projection of the second semiconductor layer of the vertical transistor on the substrate are separated from each other, and
wherein an orthographic projection of the second portion on the substrate and the orthographic projection of the first semiconductor layer on the substrate are separated from each other, and the orthographic projection of the second portion and the orthographic projection of the second semiconductor layer on the substrate have an overlapping area.

10. The memory cell according to claim 9, wherein the bit line is made of metal silicide, and the source electrode is made of doped silicon.

11. The memory cell according to claim 9, wherein the gate electrode further comprises a second gate electrode, wherein the second gate electrode is connected to the first gate electrode, and wherein the second gate electrode is disposed around outer side surfaces of the first semiconductor layer and the second semiconductor layer.

12. The memory cell according to claim 9, wherein the bit line further comprises a third portion with one end connected to the first portion and other end connected to the second portion, and
both the orthographic projection of the first semiconductor layer on the substrate and the orthographic projection of the second semiconductor layer on the substrate are separated from an orthographic projection of the third portion on the substrate.

13. A method for manufacturing a memory cell, comprising:
forming a first silicon-doped conductive layer, a sacrificial semiconductor layer, and a second silicon-doped conductive layer sequentially at a side of a substrate;
forming a plurality of first trenches through a patterning process to distinguish a plurality of transistor row regions, wherein each of the first trenches is flanked by a source row formed by the first silicon-doped conductive layer, a first sacrificial structure row formed by the sacrificial semiconductor layer, and a drain row formed by the second silicon-doped conductive layer which are stacked together;
etching back, for each of the transistor row regions, the first sacrificial structure row exposed at a side surface of the first trench to form a sacrificial structure row, wherein sidewalls of the source row, the sacrificial structure row, and the drain row form a U-shaped trench;
forming, for each of the transistor row regions, a semiconductor material layer in the U-shaped trench;
forming a plurality of second trenches perpendicular to the first trenches on the substrate through the patterning process to distinguish a plurality of transistor regions, wherein each of the transistor regions comprises a source electrode formed by the source row, a semiconductor layer formed by the semiconductor material layer, and a drain electrode formed by the drain row which are stacked together, and wherein a sacrificial structure formed by the sacrificial structure row is in the same layer as the semiconductor layer and is disposed between a first semiconductor layer and a second semiconductor layer comprised in the semiconductor layer;
removing the sacrificial structure to form a hole; and
adding a conductive material in the hole and on a sidewall of the semiconductor layer through a coating process, and patterning the conductive material to form a gate electrode comprising a first gate electrode and form a word line connected to the first gate electrode.

14. The memory cell according to claim 9, wherein the gate electrode further comprises a second gate electrode disposed at one or more of an outer side surface of the first semiconductor layer and an outer side surface of the second semiconductor layer.

15. The memory cell according to claim 11, wherein both an orthographic projection of the first gate electrode on the substrate and an orthographic projection of the second gate electrode on the substrate are within an orthographic projection of one of the source electrode and the drain electrode on the substrate.

16. The memory cell according to claim 15, wherein one of the first semiconductor layer and the second semiconductor layer has a cross-section in one of a rectangular shape and a U shape in the first direction, wherein an opening of the cross-section in the U shape faces away from the first gate electrode, and wherein the second gate electrode with a rectangular-shaped cross-section is disposed in the opening of the cross-section in the U shape.

17. The memory cell according to claim 9, wherein both an orthographic projection of the first semiconductor layer on the substrate and an orthographic projection of the second semiconductor layer on the substrate are within an orthographic projection of the source electrode on the substrate, and
both the orthographic projection of the first semiconductor layer on the substrate and the orthographic projection of the second semiconductor layer on the substrate are within an orthographic projection of the drain electrode on the substrate.

18. The memory cell according to claim 9, wherein an orthographic projection of the first semiconductor layer on the substrate and an orthographic projection of the second semiconductor layer on the substrate are separated from each other.

19. The memory cell according to claim 9, wherein cross-sections of the first semiconductor layer and the second semiconductor layer in the first direction are symmetrically distributed about a center line of the gate electrode.

20. The vertical transistor according to claim 2, wherein the vertical transistor further comprises:
a first gate insulating layer; and
a second gate insulating layer,
wherein the first gate insulating layer is disposed between the first semiconductor layer and the first gate electrode, and between the second semiconductor layer and the first gate electrode, and
wherein the second gate insulating layer is disposed between the first semiconductor layer and the second gate electrode, and between the second semiconductor layer and the second gate electrode.
